(19) United States
(12) Patent Application Publication
(10) Pub. No.: US 2006/0049523 A1
(43) Pub. Date: Mar. 9, 2006

(54) Wire-bonding method for connecting wire-bond pads and chip and the structure formed thereby

(75) Inventor: Yi Min Lin, Renwu Shiang (TW)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: ADVANCED SEMICONDUCTOR ENGINEERING, INC., Kaohsiung (TW)

(21) Appl. No.: 11/217,480

(22) Filed: Sep. 2, 2005

(30) Foreign Application Priority Data
Sep. 7, 2004 (TW) 093127001

(51) Int. Cl. H01L 23/48

(52) U.S. Cl. 257/738

(57) ABSTRACT

A wire-bonding method for connecting a wire-bond pad and a chip is characterized in that a metal ball is disposed on the wire-bond pad such that a bonding wire can be electrically connected to the wire-bond pad and raised to a certain height by the metal ball. In this arrangement, the short circuit problem caused by two adjacent wire-bond pads and impact problem on a solder mask caused by a bond head of a wire bonder during a wire bonding process can be avoided. The present invention also provides a package having a structure formed by the above-mentioned wire-bonding method.

### CROSS REFERENCE TO RELATED APPLICATION

This application claims the priority benefit of Taiwan Patent Application Serial Number 093127001, filed on Sep. 7, 2004, the full disclosure of which is incorporated herein by reference.

### BACKGROUND OF THE INVENTION

1. Field of the Invention

The present invention generally relates to a wire-bonding method, and more particularly to a wire-bonding method for connecting a wire-bond pad and a chip.

2. Description of the Related Art

In the semiconductor packaging process, a semiconductor chip is electrically connected to a packaging substrate or a lead frame through a bonding technique such as the wire bonding, the tape automatic bonding (TAB), or the flip-chip bonding technique. Even though the wire bonding technique is the earliest one to be used as compared with the tape automatic bonding (TAB) and the flip-chip bonding techniques, it is still presently and widely used due to the advantages of simply and easily being carried out; further, its associated tools, equipments and techniques have reached a stage of maturity.

FIG. 1 shows a top plan view of a conventional packaging substrate 102 having a semiconductor chip 100 electrically connected thereto by using the wire bonding technique.

FIG. 2 shows a cross-sectional view taken along line A-A of FIG. 1. Referring to FIGS. 1 and 2, the substrate 102 has an upper surface 104, and the semiconductor chip 100 is disposed on a chip area 106 defined on the upper surface 104. A plurality of conductive traces 108 are formed on the upper surface 104 of the substrate 102, wherein each of the conductive traces 108 has a section 108a, i.e. a wire-bond pad, and a terminal part 108d. The sections 108a are arranged to surround the chip area 106, and the terminal parts 108d are used for being electrically connected to other circuit contacts.

Generally, the substrate 102 has the upper surface 104 covered with a solder mask 110, and the wire-bond pads 108a thereof are exposed from the solder mask 110 for being electrically connected to the semiconductor chip 100. In addition, the semiconductor chip 100 has a plurality of pads 100a disposed on its active surface, and the pads 100a are electrically connected to the wire-bond pads 108a, respectively, through a plurality of bonding wires 112, which are formed by a wire bonding process. In addition, the semiconductor chip 100, the wire-bond pads 108a, the bonding wires 112, and parts of the substrate 102 are encapsulated by a packaging body 113.

However, the boding structure shown in FIGS. 1 and 2 has the following disadvantages:

1. When the semiconductor chip 100 has the pads 100a, i.e. I/O pads, increased in number, or when the semiconductor chip 100 is stacked with another chip (not shown), the number and density of the wire-bond pads 108a on the substrate 102 are correspondingly increased. Accordingly, when one of the bonding wires 112 is formed to connect one of the pads 100a with one corresponding wire-bond pad 108a on the substrate 102, it may cross and accidentally contact one part of an adjacent wire-bond pad 108a and thus cause a short circuit problem. Especially, the bonding wire 112a, which is connected to the pad 100a formed closer to one corner of the semiconductor chip 100, is easier to cause such a short circuit problem. For example, when the bonding wire 112a (shown within the area B of FIG. 1) is to be connected to a pad 100a, which is formed closest to one corner of the semiconductor chip 100, with the corresponding wire-bond pad 108b, it may cross and accidentally contact the adjacent wire-bond pad 108c and thus form a short circuit between the wire-bond pads 108b and 108c.

2. Since the height H of the solder mask 110 is higher than the wire-bond pads 108a, a bond head of a wire bonder (not shown), during a wire bonding process, may impact the solder mask 110 while punching a bonding wire 112 to connect with the wire-bond pad 108a. Such an impact may cause the damage of the wire bonder and the reduction of product yield.

Accordingly, the present invention provides a wire-bonding method for connecting a wire-bond pad and a chip, and a package having a structure formed by the wire-bonding method to resolve the above-mentioned problems.

### SUMMARY OF THE INVENTION

It is an object of the present invention to provide a wire-bonding method for connecting a wire-bond pad and a chip, and a package having a structure formed by the wire-bonding method, so as to solve the short circuit problem caused by two adjacent wire-bond pads on a substrate during a wire bonding process.

It is another object of the present invention to provide a wire-bonding method for connecting a wire-bond pad and a chip, and a package having a structure formed by the wire-bonding method, so as to solve the impact problem on the solder mask caused by a bond head of a wire bonder during a wire bonding process.

In order to achieve the above objects, the wire-bonding method of the present invention is characterized in that a metal ball is disposed on the wire-bond pad such that a bonding wire can be electrically connected to the wire-bond pad and raised to a certain height by the metal ball. In this arrangement, the short circuit problem caused by two adjacent wire-bond pads and impact problem on the solder mask caused by a bond head of a wire bonder during a wire bonding process can be avoided.

The package having a structure formed by the wire-bonding method of the present invention comprises a substrate, a semiconductor chip, at least one metal ball, a plurality of bonding wires, and a packaging body. The substrate has a chip area defined on its upper surface and a plurality of conductive traces disposed around the chip area, and each of the conductive traces has a wire-bond pad. The semiconductor chip is disposed on the chip area and has a plurality of pads. The metal ball is disposed on one of the wire-bond pads of the conductive traces. Each of the bonding wires electrically connects the wire-bond pad of each conductive trace with each pad of the semiconductor chip, wherein the metal ball is electrically connected between the one of the wire-bond pads and one of the bonding wires. The packaging body encapsulates the semiconductor chip, the metal ball, the plurality of bonding wires and parts of the substrate.

### BRIEF DESCRIPTION OF THE DRAWINGS

Other objects, advantages, and novel features of the invention will become more apparent from the following detailed description when taken in conjunction with the accompanying drawings.

FIG. 1 shows a top plan view of a conventional packaging substrate having a semiconductor chip electrically connected thereto by using the wire bonding technique.

FIG. 2 shows a cross-sectional view taken along line A-A of FIG. 1.

FIG. 3 shows a top plan view of a semiconductor package formed by using the wire-bonding method of the present invention.

FIG. 4 shows a cross-sectional view taken along line C-C of FIG. 3.

FIG. 5 shows an enlarged partial plan view for illustrating the positions of the metal balls on the sections of the conductive traces according to another embodiment of the present invention.

FIGS. 6-9 illustrate the wire-bonding method for connecting the sections and the semiconductor chip on the substrate as shown in FIG. 3.

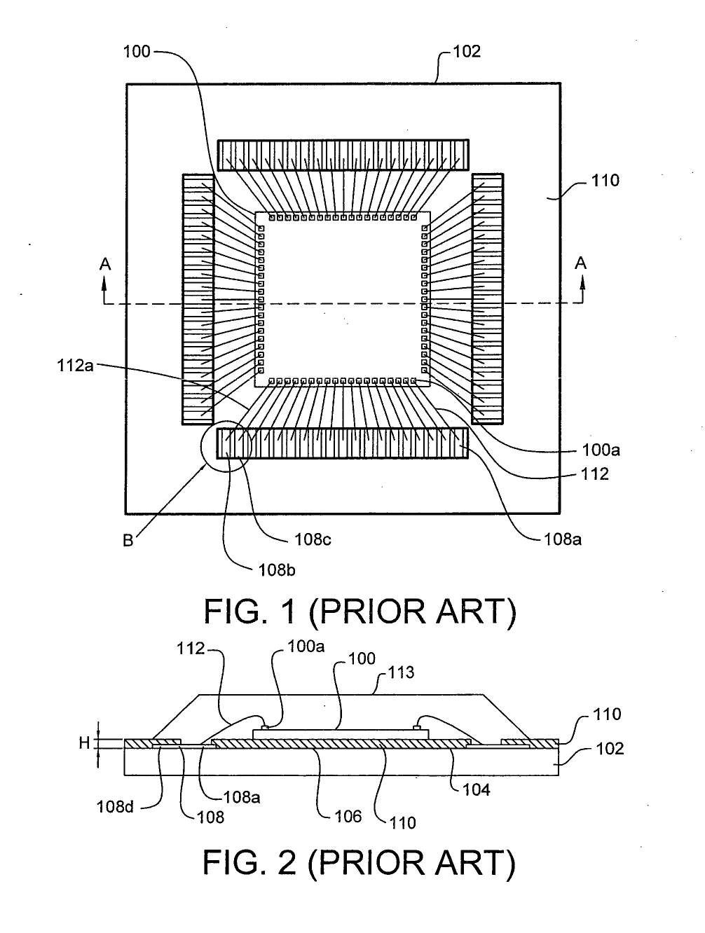

### DETAILED DESCRIPTION OF THE PREFERRED EMBODIMENT

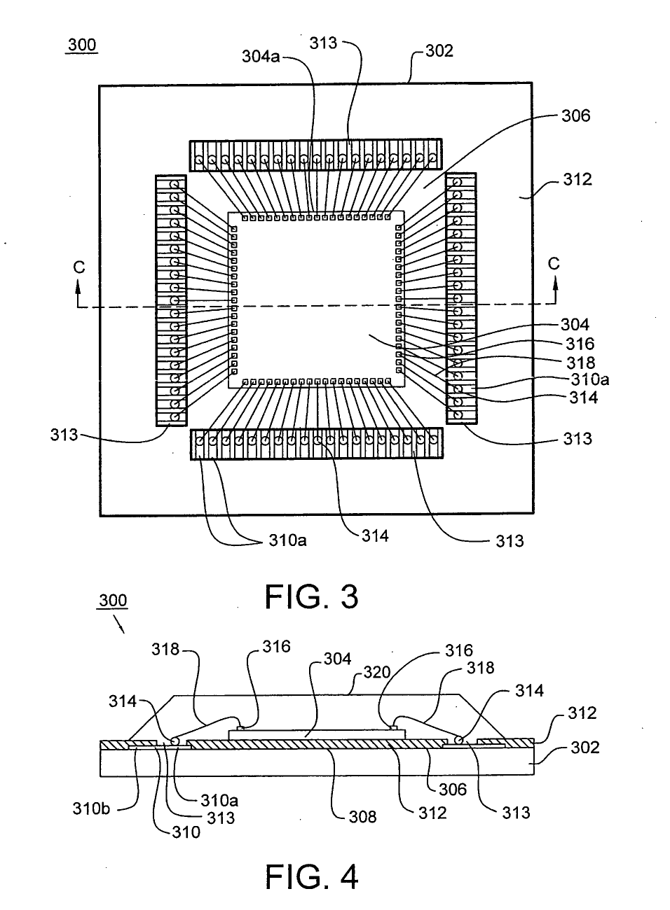

FIG. 3 shows a top plan view of a semiconductor package 300 formed by using the wire-bonding method of the present invention. FIG. 4 shows a cross-sectional view taken along line C-C of FIG. 3.

Referring to FIGS. 3 and 4, the semiconductor package 300 includes a substrate 302 and a semiconductor chip 304 disposed on the substrate 302. The substrate 302 has an upper surface 306 and a chip area 308 defined on the upper surface 306 for supporting the semiconductor chip 304. The substrate 302 further includes a plurality of conductive traces 310 formed on the upper surface 306, wherein each of the conductive traces 310 has a section 310a, also referred to as a wire-bond pad, and a terminal part 310b. The sections 310a are arranged side by side around the chip area 308, and the terminal parts 310b are used for being electrically connected to other circuit contacts. A solder mask 312 covers the conductive traces 310 with the sections 310a exposed therefrom. In this embodiment, the sections 310a of the conductive traces 310 are exposed at four openings 313 formed in the solder mask 312. The section 310a of each conductive trace 310 has a metal ball 314 disposed thereon. The metal ball 314 can be formed of any metal material for electrical connection such as gold, solder, tin-lead alloy or similar material; however, gold is preferably used in this embodiment. It should be understood that the shape and number of the openings 313 and the number of the metal balls 314 are not limited in this embodiment and can be changed according to different semiconductor package and application.

Preferably, each of the sections 310a has an anti-oxidation layer (not shown) formed thereon, and the anti-oxidation layer can be formed of metal material such as gold, nickel and so on.

The semiconductor chip 304 has a plurality of I/O (input/output) pads 316 formed thereon and arranged along each edge 304a. The I/O pads 316 are electrically connected to the metal balls 314 through a plurality of bonding wires 318, respectively, such that the semiconductor chip 304 can be electrically connected to the conductive traces 310. In addition, the terminal parts 310b of the conductive traces 310 are electrically connected to other electrical contacts (not shown), respectively, such that the semiconductor chip 304 can be electrically connected to an external circuit (not shown) through the conductive traces 310. A packaging body 302 encapsulates the semiconductor chip 304, the conductive traces 310, the metal balls 314, the bonding wires 318, and parts of the substrate 302 and the solder mask 312.

The semiconductor package 300 is characterized in that each of the sections 310, i.e. wire-bond pads, has one metal ball 314 disposed thereon, wherein the metal ball 314 raises the height of the bonding wire 318 so as to avoid the short circuit problem caused by two adjacent sections 310a, i.e. wire-bond pads, and the impact problem on the solder mask 312 caused by a bond head of a wire bonder (not shown) during a wire bonding process.

It should be understood that the wire-bonding method of the present invention is not limited to be used in the semiconductor package 300; on the contrary, it can be used in any semiconductor package having wire-bond pads and a chip. In addition, the metal ball 314 can be optionally disposed on any position at the section 310a of the conductive trace 310, or on any specific part of the conductive trace 310.

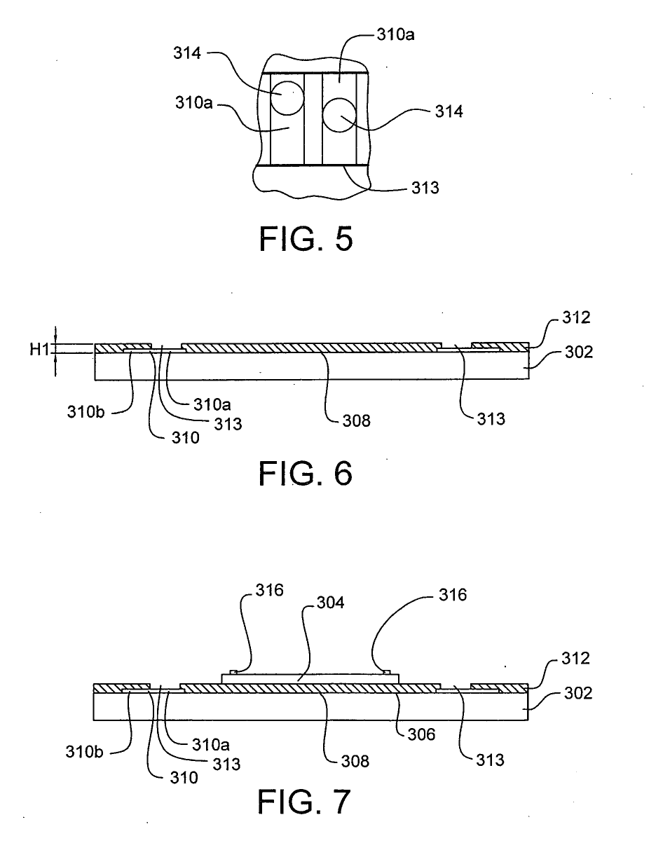

In another embodiment of the present invention, the metal balls 314 can also be respectively disposed on different positions at the sections 310a as shown in FIG. 5.

FIGS. 6-9 illustrate the wire-bonding method for connecting the sections 310, i.e. wire-bond pads, and the semiconductor chip 304 on the substrate 302. In FIGS. 6-9, the same elements are denoted by the same numerals as in FIGS. 3 and 4.

In the first step, a substrate 302 is provided as shown in FIG. 6. The substrate 302 includes a chip area 308, a plurality of conductive traces 310 and a solder mask 312 formed thereon, wherein each of the conductive traces 310 has a section 310a, i.e. wire-bond pad, exposed at one of openings 313 formed in the solder mask 312. The solder mask 312 has a thickness H1.

In the second step, a semiconductor chip 304 is disposed on the chip area 308 as shown in FIG. 7. The semiconductor chip 304 has a plurality of I/O pads 316 formed thereon.

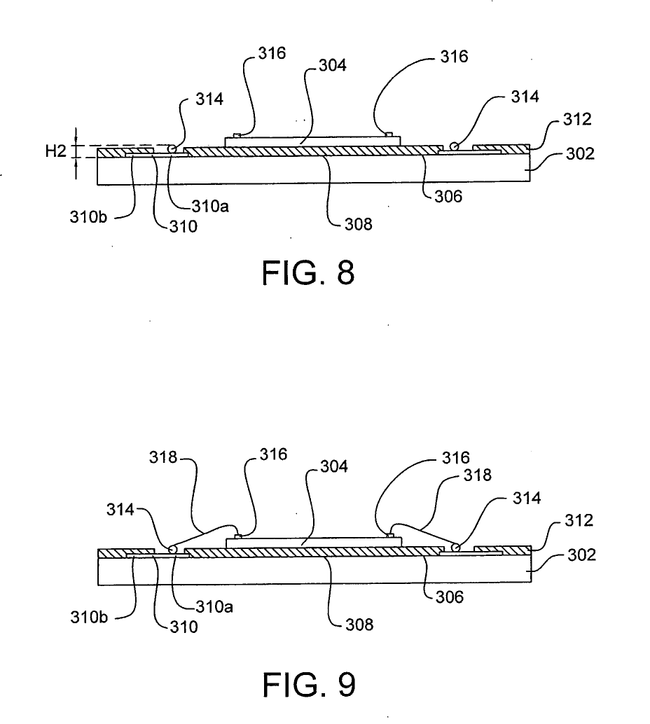

In the third step, a plurality of metal balls 314 are respectively disposed on the sections 310a, i.e. wire-bond pads, as shown in FIG. 8. Each of the metal balls 314 is electrically connected to each of the sections 310a, respectively. The metal ball 314 has a height H2 with respect to the upper surface 306 of the substrate 302. Preferably, the height H2 is greater than the thickness H1 of the solder mask 312. Preferably, the metal ball 314 has a height ranges between 0.6 mil to 0.7 mil.

In the fourth step, a bonding wire 318 is punched, by a wire bonder (not shown), between the pad 316 of the semiconductor chip 304 and the metal ball 314 as shown in FIG. 9 such that the semiconductor chip 304 is electrically connected to the conductive traces 310.

According to the above-mentioned steps, the short circuit problem caused by two adjacent wire-bond pads and the impact problem on the solder mask caused by a wire bonder in the prior art can be effectively solved.

Finally, a molding process is implemented in the structure of FIG. 9 to form a packaging body 320 as shown in FIG. 4. The packaging body 320 encapsulates the semiconductor chip 304, the conductive traces 310, the metal balls 314, the bonding wires 318, and parts of the substrate 302 and the solder mask 312.

In another embodiment of the present invention, the second and third steps are switched. That is, the plurality of metal balls 314 can be respectively disposed on the sections 310a prior to the disposition of the semiconductor chip 304 on the substrate 302.

Although the invention has been explained in relation to its preferred embodiment, it is to be understood that many other possible modifications and variations can be made without departing from the spirit and scope of the invention as hereinafter claimed.

What is claimed is:

1. A semiconductor package, comprising:
a substrate having a chip area defined on its upper surface and a plurality of conductive traces disposed around the chip area, wherein each of the conductive traces has a wire-bond pad;
a solder mask covering the conductive traces with the wire-bond pads exposed therefrom and having at least one opening formed therein, wherein the wire-bond pads of the conductive traces are exposed at the opening;
a semiconductor chip being disposed on the chip area and having a plurality of pads;
a metal ball disposed on one of the wire-bond pads of the conductive traces; and
a plurality of bonding wires each electrically connecting each wire-bond pad of the conductive traces and each pad of the semiconductor chip;
wherein the metal ball is electrically connected between the one of the wire-bond pads and one of the bonding wires; and
wherein the height of the metal ball with respect to the upper surface of the substrate is greater than the thickness of the solder mask.

2. The semiconductor package as claimed in claim 1, wherein the wire-bond pads of the conductive traces are arranged side by side around the chip area of the substrate.

3. The semiconductor package as claimed in claim 1, wherein the material of the metal ball is gold.

4. The semiconductor package as claimed in claim 1, wherein the wire-bond pad has an anti-oxidation layer formed thereon.

5. The semiconductor package as claimed in claim 4, wherein the anti-oxidation layer is formed of gold.

6. The semiconductor package as claimed in claim 4, wherein the anti-oxidation layer is formed of nickel.

7. The semiconductor package as claimed in claim 1, further comprising a packaging body encapsulating the semiconductor chip, the conductive traces, the metal ball, the bonding wires and parts of the substrate.
